(19) United States
(12) Patent Application Publication
(10) Pub. No.: US 2004/0201067 A1
(43) Pub. Date: Oct. 14, 2004

(54) LLD structure of thin film transistor

(75) Inventor: An Shih, Changhua (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Toppoly Optoelectronics Corp., Chu-Nan (TW)

(21) Appl. No.: 10/835,651

(22) Filed: Apr. 30, 2004

Related U.S. Application Data
(63) Continuation-in-part of application No. 10/263,077, filed on Oct. 2, 2002, now Pat. No. 6,747,325.

(30) Foreign Application Priority Data
Jul. 8, 2002 (TW) 091115101

(51) Int. Cl. H01L 21/00

(52) U.S. Cl. 257/408

(57) ABSTRACT

A thin film transistor having a single LDD structure with a halo structure is provided. The single LDD structure is disposed between source/drain structures, and having a first side adjacent to a first one of the source/drain structures and a second side spaced from a second one of the source/drain structures by essentially a semiconductor material. The halo structure is adjacent to the LDD structure partially or largely covering the LDD structure.

### CROSS REFERENCE TO RELATED PATENT APPLICATION

This patent application is a continuation-in-part application (CIP) of a U.S. patent application Ser. No. 10/263,077 filed Oct. 2, 2002, and now pending. The content of the related patent application is incorporated herein for reference.

### FIELD OF THE INVENTION

The present invention relates to a thin film transistor, and more particularly to a lightly doped drain (LDD) structure of the thin film transistor.

### BACKGROUND OF THE INVENTION

With the increasing development of integrated circuits, electronic devices have a tendency toward miniaturization. As is known, TFTs (Thin Film Transistors) are widely used as basic elements for controlling pixels of a TFT liquid crystal display (TFT-LCD). As a result of miniaturization, a channel between a source region and a drain region in each TFT unit will become narrower and narrower. Therefore, a short channel effect is likely to occur. Such short channel effect possibly causes the TFT unit to be undesirably turned on even when the gate voltage is zero. The switch function of the transistor is thus failed. In addition, the electric field intensity at the channel increases due to the short distance. Therefore, hot electrons in the vicinity of the drain region have a higher energy compared with the energy gap of the semiconductor. The electrons in valence bands might be promoted to conduction bands when being collided by the hot electrons, thereby producing many electron-hole pairs. Such phenomenon is also referred as a “hot electron effect”.

In a TFT-LCD, the TFT units are typically formed on a glass substrate. Since the glass substrate is generally not heat resistant, the process for producing TFTs on the LCD glass plate should be a low-temperature manufacturing process. In order to minimize the hot electron effect, a low-temperature polysilicon thin film transistor (LTPS-TFT) having LDD (lightly doped drain) structures was developed. In these LTPS-TFTs, a gate-drain overlapped LDD (GO-LD) structure was widely employed.

A process for producing such an N-type LTPS-TFT is illustrated with reference to FIGS. 1(a) to 1(g). In FIG. 1(a), a silicon-oxide buffer layer 11 and an intrinsic amorphous silicon (i-a-Si) layer are sequentially formed on a glass substrate 10. Then, the i-a-Si layer is converted to an intrinsic polysilcon (i-poly-Si) layer 12 by a laser annealing procedure. Then, by a micro-photolithography and etching procedure, the i-poly-Si layer 12 is partially etched to form a desired polysilicon structure 120, as can be seen in FIG. 1(b). In FIG. 1(c), a photoresist layer is formed on the polysilicon structure 120 and properly patterned to be a mask 13. Then, two N-type regions 121 and 122 are formed on a portion of the polysilicon structure 12 exposed from the mask 13 by an ion implantation procedure. The two N-type regions 121 and 122 serve as source/drain regions of an N-channel TFT. After the photoresist mask 13 is removed, a gate insulator 14, for example made of silicon dioxide, is formed on the resulting structure of FIG. 1(c), as shown in FIG. 1(d). In FIG. 1(e), a gate electrode 15 is then formed on the gate insulator 14 by sputtering and patterning a gate conductive layer on the resulting structure of FIG. 1(d). Then, by a lightly ion implantation procedure with the gate electrode 15 serving as a mask to provide trace N-type dopants into the polysilicon structure 120, two LDD (lightly doped drain) regions 123 and 124 are formed immediately adjacent to the drain/source regions 121 and 122, respectively. In FIG. 1(f), an interlayer dielectric layer 17 is formed on the resulting structure of FIG. 1(e). Then, a proper number of contact holes directing to the gate electrode and source/drain regions are created. Afterwards, as shown in FIG. 1(g), a conductive layer is sputtered on the resulting structure of FIG. 1(f), fills the contact holes, and then patterned to form a gate conductive line 190 and a source/drain conductive line 191.

The gate-drain overlapped LDD (GO-LD) structure results in a reduced electric field intensity in the vicinity of the drain region so as to slightly diminish the influence of the hot electron effect. However, with the increasing demand of high resolution of the display, the circuitry is more and more complicated than ever. In other words, the number of the electronic devices increases significantly so as to reduce the space of a single electronic device. Accordingly, the channels of transistors will become narrower and narrower. Furthermore, the LDD regions shorten the channel to an extent, and thus depletion regions in the vicinity of the source/drain regions will be relative close and even reachable to each other. Therefore, current leakage and punch-through problems may occur so as to deteriorate the electronic devices. The above-described effects will be even significant with the increasing development toward miniaturization.

### SUMMARY OF THE INVENTION

The present invention provides a thin film transistor having diminished hot electron, current leakage and punch-through effects.

A first aspect of the present invention relates to a thin film transistor, which includes a semiconductor layer formed of polycrystalline silicon; source/drain structures formed apart from each other in the semiconductor layer; a single LDD structure disposed between the source/drain structures, and having a first side adjacent to a first one of the source/drain structures and a second side opposed to the first side; a halo structure having a third side adjacent to the second side of the LDD structure, and a fourth side spaced from a second one of the source/drain structures by the semiconductor material; a gate structure formed over the semiconductor layer; and an insulator layer disposed between the semiconductor layer and the gate electrode for insulating the gate electrode from the source/drain structures and the LDD and the halo structures.

In an embodiment, the LDD structure is a gate-drain overlapped LDD.

In an embodiment, the thin film transistor is of an N-type, the LDD structure contains a doping material selected from a group consisting of P ions, As ions, PHₓ ions, AsHₓ ions and a combination thereof, and the halo structure contains doping material selected from a group consisting of B ions, BHₓ ion, B₂Hₓ ions and a combination thereof.

In an embodiment, at least a portion of the LDD structure is exposed from the halo structure and the source/drain structures.

In another embodiment, the LDD structure is enclosed with the halo structure and the first one of the source/drain structures.

Another aspect of the present invention relates to a thin film transistor, which includes a semiconductor layer formed of a semiconductor material; source/drain structures formed apart from each other in the semiconductor layer; a single LDD structure disposed between the source/drain structures, and having a first side adjacent to a first one of the source/drain structures and a second side opposed to the first side; a halo structure having a third side adjacent to the second side of the LDD structure, and a fourth side spaced from a second one of the source/drain structures by the semiconductor material; a gate structure formed over the semiconductor layer; and an insulator layer disposed between the semiconductor layer and the gate electrode for insulating the gate electrode from the source/drain structures and the LDD and the halo structures. The thin film transistor is of an N-type, the LDD structure contains a doping material selected from a group consisting of P ions, As ions, PHₓ ions, AsHₓ ions and a combination thereof, and the halo structure contains more than one_doping material selected from a group consisting of B ions, BHₓ ion, B₂Hₓ ions and a combination thereof.

According to a third aspect of the present invention, a thin film transistor includes a semiconductor layer formed of polycrystalline silicon; source/drain structures formed apart from each other in the semiconductor layer; a single LDD structure disposed between the source/drain structures, and having a first side adjacent to a first one of the source/drain structures and a second side opposed to the first side; a halo structure having a third side adjacent to the second side of the LDD structure, and a fourth side spaced from a second one of the source/drain structures by the semiconductor material; a gate structure formed over the semiconductor layer; and an insulator layer disposed between the semiconductor layer and the gate electrode for insulating the gate electrode from the source/drain structures and the LDD and the halo structures. At least a portion of the LDD structure is exposed from the halo structures and the first one of source/drain structures.

The above objects and advantages of the present invention will become more readily apparent to those ordinarily skilled in the art after reviewing the following detailed description and accompanying drawings, in which:

### BRIEF DESCRIPTION OF THE DRAWINGS

FIGS. 1(a) to 1(g) are schematic cross-sectional views illustrating a conventional process for producing a TFT having LDD structures;

FIGS. 2(a) to 2(g) are schematic cross-sectional views illustrating a process for producing a TFT having a single LDD structure with a halo structure according to an embodiment of the present invention;

FIG. 3 is a schematic cross-sectional view illustrating another TFT having a single LDD structure with an alternative halo structure according to another embodiment of the present invention;

FIGS. 4(a) to 4(g) are schematic cross-sectional views illustrating a process for producing a TFT having a single LDD structure with a halo structure according to a further embodiment of the present invention; and

FIG. 5 is a schematic cross-sectional view illustrating a further TFT having a single LDD structure with an alternative halo structure according to a still further embodiment of the present invention.

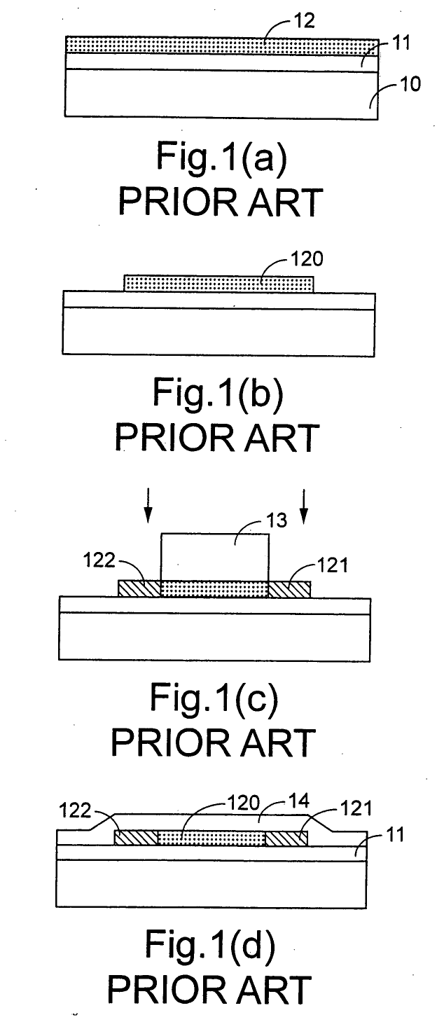

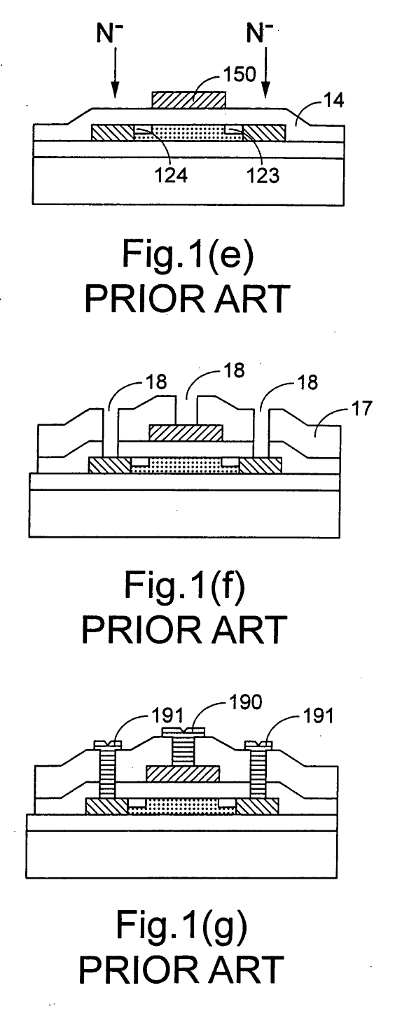

### DETAILED DESCRIPTION OF THE PREFERRED EMBODIMENT

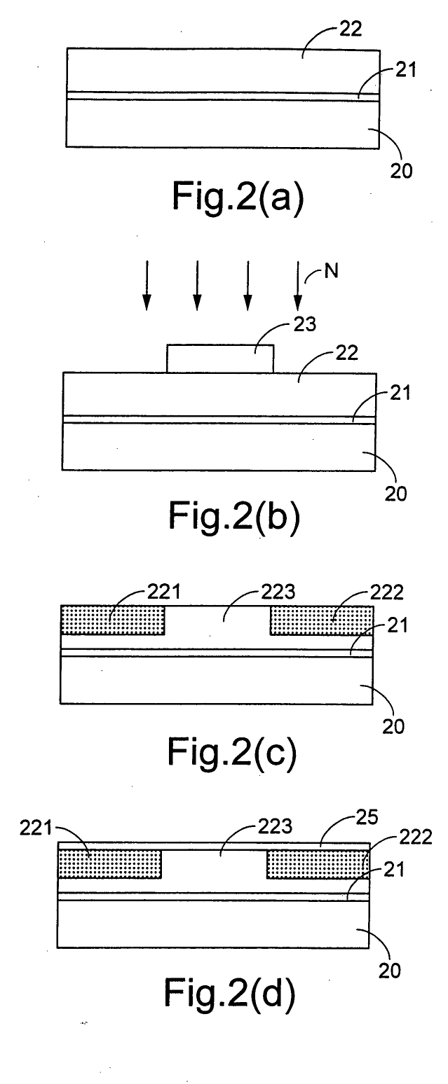

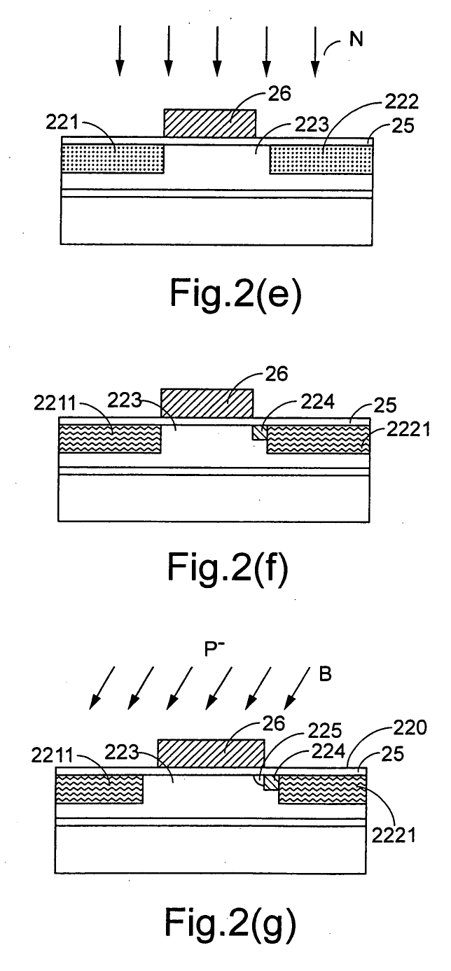

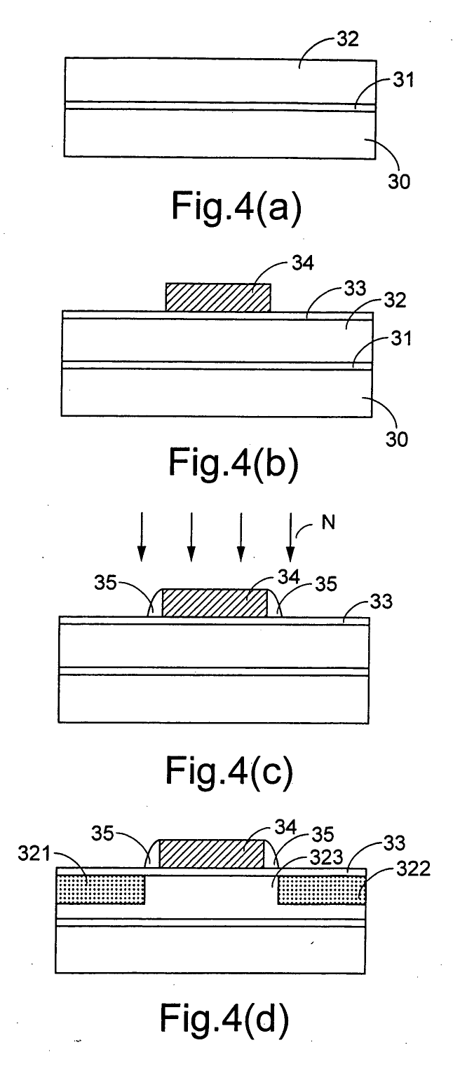

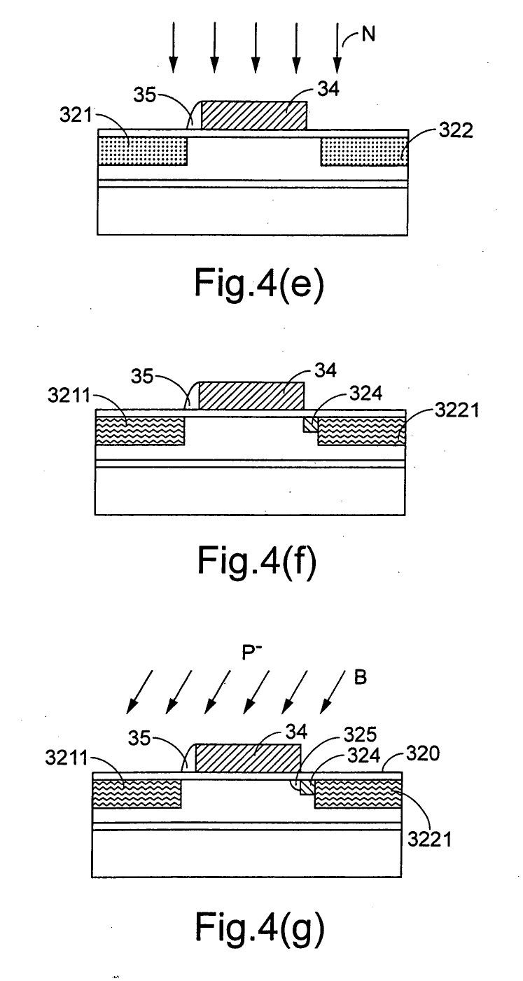

For the purpose of preventing from possible contact of the depletion regions in the vicinity of the source/drain regions with each other, the present invention provides a TFT having a single LDD structure with a halo structure so that the source/drain depletion regions will not be that close to each other as in the prior art. Two examples of such TFTs and processes for producing the same are illustrated with reference to FIGS. 2(a) to 2(g) and 4(a) to 4(g), respectively.

As shown in FIG. 2(a), a buffer layer 21 is formed on a glass substrate 20. An intrinsic amorphous silicon (i-a-Si) layer is subsequently formed on the buffer layer 21, and the i-a-Si layer is further converted to an intrinsic polysilcon (i-poly-Si) layer 22 by a laser annealing procedure. A photoresist layer is then formed on the polysilicon layer 22 and properly patterned to be a mask 23 via a micro-lithographic and etching process, and two N-type regions 221 and 222 are formed in the polysilicon layer 22 exposed from the mask 23 by an N-type ion implantation procedure, as shown in FIGS. 2(b) and 2(c). The two N-type regions 221 and 222 are apart from each other by a channel region 223. Then, the photoresist mask 23 is removed. Referring to FIG. 2(d), a gate insulator 25 is formed on the resulting structure of FIG. 2(c). As shown in FIG. 2(e), a gate electrode 26 having a width slightly less than the length of the channel 223 is then formed on the gate insulator 25 via patterning and etching procedures such that an end portion of the channel region 223 is exposed and uncovered by the gate electrode 26. Then, by a lightly ion implantation procedure with the gate electrode 26 serving as a mask to provide trace N-type dopants into the exposed portion of the polysilicon layer 22, a single LDD structure 224 is formed in the polysilicon layer 22, as can be seen in FIG. 2(f), and the N-type regions 221 and 222 are consequently heavily doped to form the source/drain regions 2211 and 2221. Further, an ion implantation procedure is performed with the gate electrode 26 as a mask to inject a P-type doping material into the polysilicon layer 22 in a direction B deviating from the surface 220 of the polysilicon layer 22 by a certain angle. For example, the certain angle can be ranged between 0° and 30°. Therefore, a P-type halo region 225 is formed immediately next to the LDD structure 224, as shown in FIG. 2(g). Afterwards, an interlayer dielectric layer, contact holes, gate and source/drain conductive lines and any other required structures are sequentially formed on the resulting structure of FIG. 2(g) to complete the TFT. Due to the gradual distribution of dopant concentration resulting from slant implantation, the width of the depletion regions interfacing the channel region with the source/drain regions is reduced so as to minimize current leakage and punch through effects.

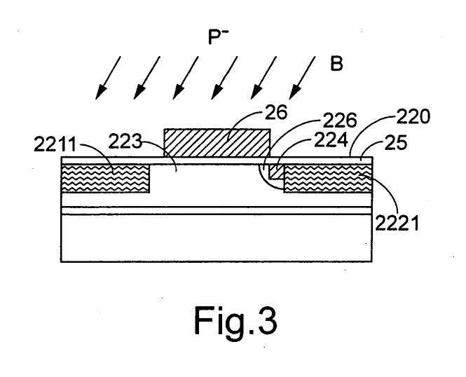

In the embodiment shown in FIG. 2(g), the halo region 225 is formed beside the LDD structure 224 with partial LDD structure 224 exposed from the halo structure 225. Alternatively, the LDD structure 224 exposed from the source/drain structure 2221 and the gate insulator 25 can be completely enclosed with the halo structure 226, as shown in FIG. 3, to achieve similar function.

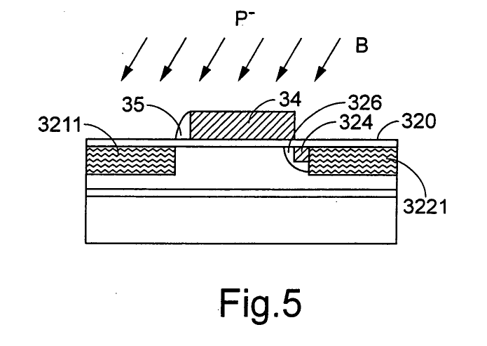

Another example of the process for producing a TFT having a single LDD structure with a halo structure according to the present invention will be described hereinafter. A buffer layer 31 is formed on a glass substrate 30. An intrinsic amorphous silicon (i-a-Si) layer is sequentially formed on the buffer layer 31, and the i-a-Si layer is further converted to an intrinsic polysilcon (i-poly-Si) layer 32 by a laser annealing procedure, as shown in FIG. 4(a). As shown in FIG. 4(b), a gate insulator 33 is formed on the polysilicon layer 32, and a gate structure 34 of a desired pattern is formed on the gate insulator 33. Further, as shown in FIGS. 4(c) and 4(d), a dielectric layer overlies the resulting structure of FIG. 4(b), and is patterned to form a spacer or sidewalls 35 beside the gate structure 34 via a micro-lithographic and etching process. The gate electrode 34 and its spacer/sidewalls 35 serve as a doping mask for a following N-type ion implatation procedure, thereby forming two N-type regions 321 and 322 in the polysilicon layer 32 exposed from the doping mask. The two N-type regions 321 and 322 are apart from each other by a channel region 323. Then, as shown in FIG. 4(e), a portion of the space 35 adacent to the N-type region 322 is removed such that an end portion of the channel region 223 is exposed. By a lightly ion implantation procedure with the gate electrode 34 and the remaining spacer 35 serving as a doing mask to provide trace N-type dopants into the exposed portion of the polysilicon layer 32, a single LDD structure 324 is formed in the polysilicon layer 32, as can be seen in FIG. 4(f), and the N-type-regions are simultaneously heavily doped to form source/drain structures 3211 and 3221. Further, an ion implantation procedure is performed with the gate electrode 34 as a mask to inject a P-type doping material into the polysilicon layer 32 in a direction B deviating from the surface 320 of the polysilicon layer 32 by a certain angle. For example, the certain angle can be ranged between 0° and 30°. Therefore, a P-type halo region 325 is formed immediately next to the LDD structure 324, as shown in FIG. 4(g). Afterwards, the following necessary steps, e.g. the similar subsequent steps as described in the above embodiment, are performed. The LDD structure 324, as mentioned above, can be covered with the halo structure 325 to various extents. Another example that the LDD structure 324 is completely enclosed with the halo structure 326 is shown in FIG. 5.

Since each of the above-mentioned TFTs has a single LDD structure, the distance between the depletion regions in the vicinity of the source/drain regions could be somewhat increased, compared to those with two LDD structures. Therefore, the hot electron, current leakage and punch-through effects occurred in the prior art are considerably diminished. They are particularly suitable for use in a driver circuit and other application circuits. At the presence of the halo structure, the pixel units are further made to comply with the operational modes of a TFT.

The ion implantation procedures mentioned above, for example, can also be substituted by ion shower procedures. In the above embodiments, the gate conductor is formed by sputtering with chromium, tungsten molybdenum, tantalum, aluminum or copper and has a thickness of about 100 nm. The buffer layer generally has a thickness of about 600 nm and is formed of silicon nitride, silicon oxide or a combination thereof by a plasma enhanced chemical vapor deposition (PECVD) procedure. The interlayer dielectric layer generally has a thickness of about 600 nm and is formed of silicon dioxide by a plasma enhanced chemical vapor deposition (PECVD) procedure. The gate insulator used generally has a thickness of about 100 nm and is formed of silicon dioxide by a plasma enhanced chemical vapor deposition (PECVD) procedure. An amorphous silicon layer having a thickness of about 100 nm is employed to form the polysilicon layer in the above embodiments by a laser annealing/crystallizing procedure. Preferably, the amorphous silicon layer needs to be dehydrogenated for 30 min in a high temperature furnace at 400° C. prior to the laser annealing/crystallizing procedure. During the laser annealing/crystallizing procedure, the energy for carrying out the laser annealing/crystallizing procedure is selected such that at least 100 shots are provided at 350 mJ/cm². In addition, the dopant concentration in the above-described ion implantation procedure ranges from 1×10¹⁴ to 2×10¹⁵ cm⁻² for the N-type dopants, and about 1×10¹² for the P-type dopants. The P-type dopant can be selected from B ions, BHₓ ions, B₂Hₓ ions or a combination thereof, and the N-type dopant can be selected from P ions, As ions, PHₓ ions, AsHₓ ions and a combination thereof. The contact holes are formed by a reactive ion etching procedure.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A thin film transistor, comprising:
a semiconductor layer formed of polycrystalline silicon;
source/drain structures formed apart from each other in said semiconductor layer;
a single LDD structure disposed between said source/drain structures, and having a first side adjacent to a first one of said source/drain structures and a second side opposed to said first side;
a halo structure having a third side adjacent to said second side of said LDD structure, and a fourth side spaced from a second one of said source/drain structures by said semiconductor material;
a gate structure formed over said semiconductor layer; and
an insulator layer disposed between said semiconductor layer and said gate electrode for insulating said gate electrode from said source/drain structures and said LDD and said halo structures.

2. The thin film transistor according to claim 1 wherein said LDD structure is a gate-drain overlapped LDD.

3. The thin film transistor according to claim 1 wherein said thin film transistor is of an N-type, said LDD structure contains a doping material selected from a group consisting of P ions, As ions, PHₓ ions, AsHₓ ions and a combination thereof, and said halo structure contains doping material selected from a group consisting of B ions, BHₓ ion, B₂Hₓ ions and a combination thereof.

4. The thin film transistor according to claim 1 wherein at least a portion of said LDD structure is exposed from said halo structure and said source/drain structures.

5. The thin film transistor according to claim 1 wherein said LDD structure is enclosed with said halo structure and said first one of said source/drain structures.

6. A thin film transistor, comprising:
a semiconductor layer formed of a semiconductor material;
source/drain structures formed apart from each other in said semiconductor layer;
a single LDD structure disposed between said source/drain structures, and having a first side adjacent to a first one of said source/drain structures and a second side opposed to said first side;
a halo structure having a third side adjacent to said second side of said LDD structure, and a fourth side spaced from a second one of said source/drain structures by said semiconductor material;
a gate structure formed over said semiconductor layer; and
an insulator layer disposed between said semiconductor layer and said gate electrode for insulating said gate electrode from said source/drain structures and said LDD and said halo structures,
wherein said thin film transistor is of an N-type, said LDD structure contains a doping material selected from a group consisting of P ions, As ions, PHₓ ions, AsHₓ ions and a combination thereof, and said halo structure contains more than one_doping material selected from a group consisting of B ions, BHₓ ion, B₂Hₓ ions and a combination thereof.

7. The thin film transistor according to claim 6 wherein at least a portion of said LDD structure is exposed from said halo structure and said source/drain structures.

8. The thin film transistor according to claim 6 wherein said LDD structure is enclosed with said halo structure and said first one of said source/drain structures.

9. The thin film transistor according to claim 6 wherein said LDD structure is a gate-drain overlapped LDD.

10. The thin film transistor according to claim 6 wherein said first one of said source/drain structures is the drain structure, and said second one of said source/drain structures is the source structure.

11. The thin film transistor according to claim 6 wherein said semiconductor material is polycrystalline silicon.

12. The thin film transistor according to claim 6 wherein said semiconductor layer is disposed on a glass substrate.

13. A thin film transistor, comprising:
a semiconductor layer formed of polycrystalline silicon;
source/drain structures formed apart from each other in said semiconductor layer;
a single LDD structure disposed between said source/drain structures, and having a first side adjacent to a first one of said source/drain structures and a second side opposed to said first side;
a halo structure having a third side adjacent to said second side of said LDD structure, and a fourth side spaced from a second one of said source/drain structures by said semiconductor material;
a gate structure formed over said semiconductor layer; and
an insulator layer disposed between said semiconductor layer and said gate electrode for insulating said gate electrode from said source/drain structures and said LDD and said halo structures,
wherein at least a portion of said LDD structure is exposed from said halo structure and said first one of source/drain structure.

14. The thin film transistor according to claim 13 wherein said LDD structure is a gate-drain overlapped LDD.

15. The thin film transistor according to claim 13 wherein said thin film transistor is of an N-type, said LDD structure contains a doping material selected from a group consisting of P ions, As ions, PHₓ ions, AsHₓ ions and a combination thereof, and said halo structure contains doping material selected from a group consisting of B ions, BHₓ ion, B₂Hₓ ions and a combination thereof.
